(19) United States
(12) Patent Application Publication
(10) Pub. No.: US 2009/0101968 A1
(43) Pub. Date: Apr. 23, 2009

(54) STRUCTURE OF SEMICONDUCTOR DEVICE AND MANUFACTURING METHOD OF THE SAME

(75) Inventor: Shigeru SUGIOKA, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/255,480

(22) Filed: Oct. 21, 2008

(30) Foreign Application Priority Data
Oct. 23, 2007 (JP) 2007-275038

(51) Int. Cl. H01L 47/00

(52) U.S. Cl. 257/327; 257/E47.001

(57) ABSTRACT

A field effect transistor configured in a convex type Fin structure, in which diffusion layer 104 serving as source and drain regions is formed in a semiconductor layer that is sandwiched by STI regions 105 and projected upward of the isolation region, and which has a gate electrode overlapping a channel region between the source and drain regions, the field effect transistor including: side walls 110b on the sides of the diffusion layer serving as the source and drain regions; selective epitaxial growth silicon layer 111 on the upper surface of the diffusion layer sandwiched by the side walls; and contact plug 115 connected to the selective epitaxial growth silicon layer.

### BACKGROUND OF THE INVENTION

1. Field of the Invention

The present invention relates to a structure of a semiconductor device and a manufacturing method thereof. More particularly, the present invention relates to a structure of a semiconductor device, which is capable of improving a problem in the case where contacts are formed in source and drain regions of a convex type Fin-FET (Fin Field Effect Transistor), and relates to a manufacturing method of the semiconductor device having such structure.

2. Description of the Related Art

Along with the advancement of miniaturization of semiconductor elements, not only the gate length (channel length) but also the diffusion layer width (channel width) of a transistor has been increasingly reduced. Recently, attention has been given to a Fin-FET, which uses not only the upper surface but also the side surface of the diffusion layer of the transistor as the channel to gain the on-state current (see National Publication of International Patent Application No. 2006-501672 and Japanese Patent Laid-Open No. 2005-310921).

Further, when the diffusion layer width (in the shorter side direction) of the Fin-FET is reduced to about 30 nm (where Lg (gate length)>W (diffusion layer width)), the channel region can be completely depleted, so that an excellent off-state current (I_{off}) characteristic can be obtained. Further, the Fin-FET has a double gate structure and hence has a more excellent gate control characteristic as compared with a planar type transistor. For this reason, the Fin-FET is expected as a completely depleted transistor having excellent sub-threshold characteristics.

In the above described patent documents, Fin-shaped semiconductor layers are formed on an SOI substrate, and hence there is a problem that parasitic resistance is increased in the diffusion layer.

On the other hand, there is disclosed a technique in which the Fin is formed by etching a bulk silicon substrate without using the expensive SOI substrate (Japanese Patent Laid-Open No. 2002-118255, Japanese Patent Laid-Open No. 2006-13521 and Japanese Patent Laid-Open No. 5-218415).

Further, there has been proposed a method in which a Fin-FET is formed in such a manner that after formation of STI (Shallow Trench Isolation), an insulating film buried in the STI is dug down by using a dry or wet technique so as to expose the side surface of the diffusion layer, and that the gate electrode is laid on the upper and side surfaces of the diffusion layer.

However, the width of the diffusion layer is only about 30 nm, which results in a problem that the parasitic resistance of contacts needs to be reduced. As one of the methods to solve the problem, there has been considered a method for reducing the parasitic resistance in such a manner that an epitaxial silicon is selectively grown on the side wall of the diffusion layer to thereby make the size of the contact bottom larger than the width of the diffusion layer.

In the case where a convex type Fin-FET is produced, there is a possibility that when the epitaxial silicon is selectively grown on the surface of the diffusion layer side, the epitaxial silicon is made to grow on the side surface of the diffusion layer. This results in a problem that when the space separating the diffusion layers is reduced due to the advancement of miniaturization, a short circuit is caused in this portion.

### SUMMARY OF THE INVENTION

The invention seeks to solve one or more of the above problems, or to improve upon those problems at least in part.

As a result of an extensive investigation of the above described problems, the present inventors have found, as a method for surely reducing the parasitic resistance, a method in which before an epitaxial silicon is selectively grown, a side wall (SW) is formed on the side surface of the diffusion layer so that the epitaxial silicon is selectively grown only on the upper surface of the diffusion layer.

In one embodiment, there is provided a semiconductor device that includes: a field effect transistor configured in a convex type Fin structure having a diffusion layer serving as source and drain regions formed in a semiconductor layer that is sandwiched by shallow trench isolation (STI) regions and projected upward of the isolation region; and having a gate electrode overlapping a channel region between the source and drain regions, the semiconductor device including: side walls on the sides of the diffusion layer serving as the source and drain regions; a selective epitaxial growth silicon layer on the upper surface of the diffusion layer sandwiched by the side walls; and a contact plug connected to the selective epitaxial growth silicon layer.

In the present invention, the selective epitaxial growth silicon layer is formed only on the upper surface of the diffusion layer sandwiched by the side walls. Thus, even in the case of miniaturization, the selective epitaxial growth silicon layers can be prevented from being brought into contact with each other and short-circuited with each other, and the bottom size of the contact can be made larger than the width of the diffusion layer. Thereby, it is possible to reduce the parasitic resistance in the source and drain regions.

Further, in the present invention, when phosphorus and arsenic are implanted after cell contact holes are opened, the phosphorus and arsenic can be implanted into the surface of epitaxial growth silicon at a high concentration by using the epitaxial growth silicon, so that the parasitic resistance (contact resistance) can be reduced. Further, the distance between the bottom of the cell contact plug and the end of the gate electrode is increased, so that a margin for the leakage of phosphorus from the cell contact plug is increased. For this reason, it is possible to increase the impurity concentration of the phosphorus doped amorphous silicon film in the cell contact plug, so that the parasitic resistance can be further reduced.

### BRIEF DESCRIPTION OF THE DRAWINGS

The above features and advantages of the present invention will be more apparent from the following description of certain preferred embodiments taken in conjunction with the accompanying drawings, in which:

FIG. 1 shows a layout diagram (FIG. 1(a)) of a memory cell array of a DRAM using Fin-FETs, a partially enlarged view of the memory cell array (FIG. 1(b)), and a bird's eye view (FIG. 1(c)) from the direction F in FIG. 1(b), which shows a structure of the Fin-FET. Note that in the bird's eye view, a part of the side walls 10 and 10′ is removed for explanation, and a contact plug, an interlayer insulating film and the like are not shown;

FIG. 2 to FIG. 12 and FIG. 14 show cross sections of a semiconductor device, which represent the order of forming processes of a Fin-FET portion to explain a first exemplary embodiment of a manufacturing method according to the present invention. In the figures, each (a) shows sectional views along the line A-A in FIG. 1(b), each (b) shows sectional views along the line B-B in FIG. 1(b), each (c) shows sectional views along the line C-C in FIG. 1(b), each (d) shows sectional views along the line D-D in FIG. 1(b), and each (e) shows sectional views along the line E-E in FIG. 1(b);

FIG. 13 shows a top view after the process shown in FIG. 12;

FIG. 15 is a sectional view of a part of processes for explaining a second exemplary embodiment; and

FIG. 16 is a sectional view showing an example of a semiconductor device according to the present invention, which is subjected to the processes up to formation of a capacitance plate of capacitors.

### DETAILED DESCRIPTION OF THE PREFERRED EMBODIMENTS

The present invention relates to a semiconductor device using convex type Fin-FETs in a cell array of a dynamic random access memory (hereinafter referred to as DRAM), and relates to a manufacturing method of the semiconductor device.

The invention will be now described herein with reference to illustrative embodiments. Those skilled in the art will recognize that many alternative embodiments can be accomplished using the teachings of the present invention and that the invention is not limited to the embodiments illustrated for explanatory purpose.

### First Exemplary Embodiment

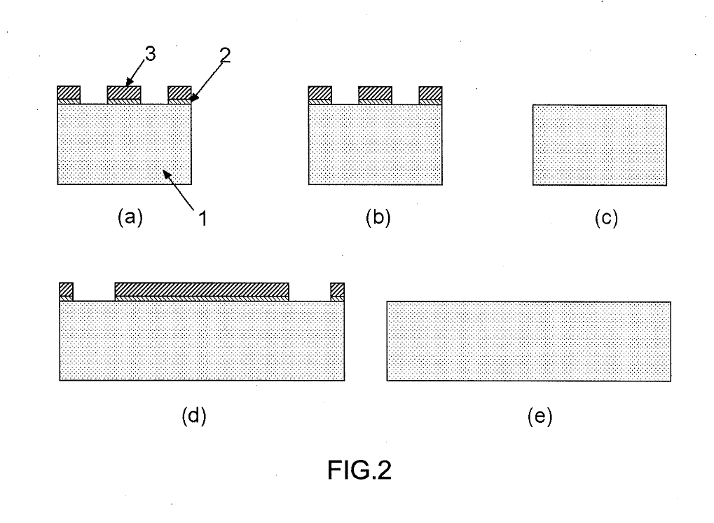

FIG. 2 to FIG. 14 show cross sections of a semiconductor device, which represent the order of forming processes of a Fin-FET portion to explain an exemplary embodiment of a manufacturing method according to the present invention. A sectional view of transistors in the peripheral region is not illustrated in the figure of the exemplary embodiment.

First, as shown in FIG. 2, pad oxide film 2 having a thickness of about 9 nm and field nitride film 3 having a thickness of about 120 nm are successively formed on semiconductor substrate 1. Field nitride film 3 serves as a mask layer covering a diffusion layer, and is also used as a stopper at the time of CMP (Chemical Mechanical Polishing) of an oxide film which is buried in the STI. Then, patterning is performed by using a lithography technique and a dry etching technique, so that field nitride film 3 and pad oxide film 2 are removed so as to open a STI forming region. Further, Si is etched to a depth of about 200 nm by a dry technique using field nitride film 3 as a mask. At this time, a taper angle of diffusion layer 4 is set to 85° or more to less than 90°. Note that the upper surface of field nitride film 3 is also etched by about 50 nm at this time.

When the Fin-FET is used in the cell array of a DRAM, a diffusion layer width (in the shorter side direction of convex diffusion layer 4 (semiconductor layer)) of about 30 nm or less needs to be targeted to realize miniaturization in the gate width direction and a completely depleted device using the Fin-FET. To this end, after the above described field nitride film is patterned, the field nitride film mask before Si etching is slimmed down to about 60 nm or less by the dry etching or the wet etching, and then Si etching is performed. As a result of a subsequent oxidization process, and the like, the width of the diffusion layer is reduced to about 30 nm or less.

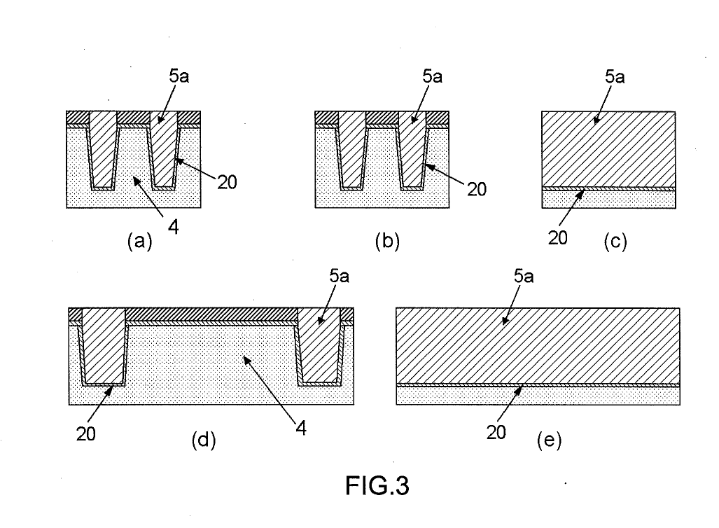

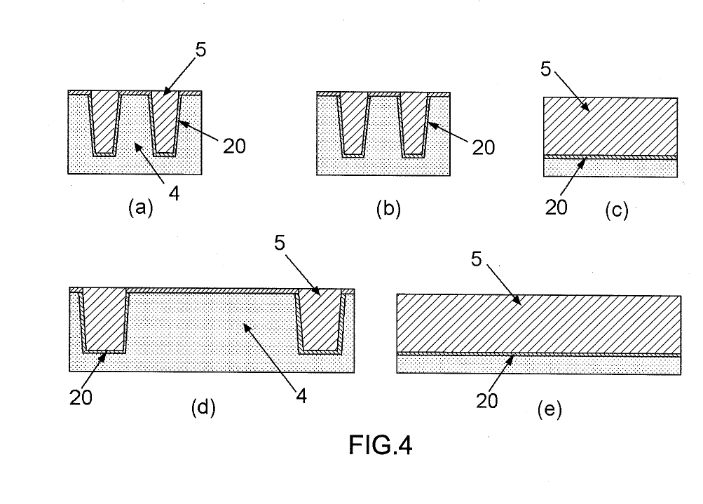

After the Si etching, silicon oxide film 20 is formed in the isolation trench by a thermal oxidation method, to remove etching damage and to protect diffusion layer 4 from the plasma of the HDP-CVD (High Density Plasma Chemical Vapor Deposition) method as will be described below. Then, silicon oxide film 5a is formed by the HDP-CVD method. Thereafter, silicon oxide film 5a is polished and removed by the CMP method by using silicon nitride film 3 as a stopper (FIG. 3), so as to be used as the isolation region. After the CMP, the oxide film is wet etched for adjusting the height of the STI oxide film. Then, silicon nitride film 3 is removed by wet etching. Thereby, isolation region (STI) 5 is formed (FIG. 4).

Next, impurities are implanted to form wells and channels of transistors in the cell region and the peripheral region, and are heat treated so as to be activated (not shown). The Fin-FET has an excellent gate control characteristic as compared with a planar type transistor. Thus, in the Fin-FET, the channel doping for threshold adjustment is not performed, or even when the channel doping is performed, acceptor impurities are implanted at a low concentration so that the impurity concentration in the channel region is prevented from exceeding about 1.0×10¹⁸ cm⁻³.

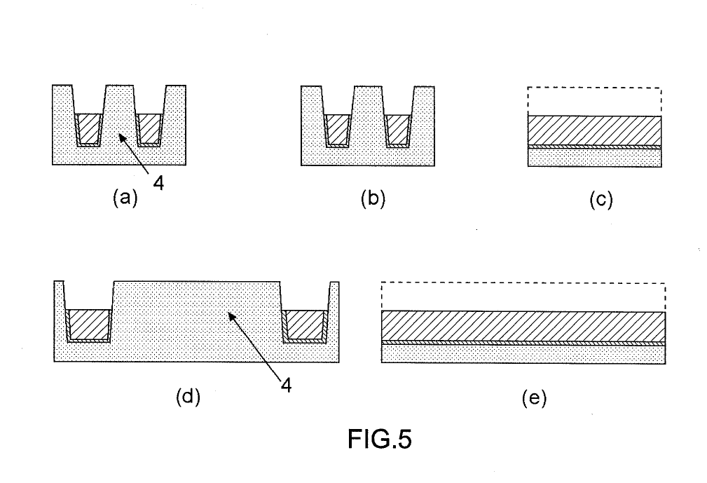

Subsequently, in the above described structure, the applied resist (not shown) is opened only in the inside of the cell array by using the lithography technique, and the STI oxide film of isolation region 5 is etched to a depth of about 100 nm by the wet or dry etching technique. Thereafter, the resist is removed by ashing (FIG. 5). At this time, in the etched region, pad oxide film 2 and silicon oxide film 20 are also removed, so that the surface of diffusion layer 4 is exposed.

In the exemplary embodiment, the silicon oxide film is buried in isolation region (STI) 5. However, further miniaturization of the device prevents the silicon oxide film from being buried in isolation region (STI) 5 sufficiently. For this reason, an SOG (Spin-On-Glass) monolayer, or a laminated structure of the SOG and a silicon oxide film may also be used in preparation for the further miniaturization. When the SOG is reformed, a high temperature heat treatment is applied. Thus, a silicon nitride film or a silicon oxynitride film is used as a liner film. For this reason, in the case where the liner structure is used, when the insulating film buried in the STI is removed, the silicon oxide film is first etched to about 100 nm. Thereafter, a process of removing the liner film is added, and further, silicon oxide film 20 is removed.

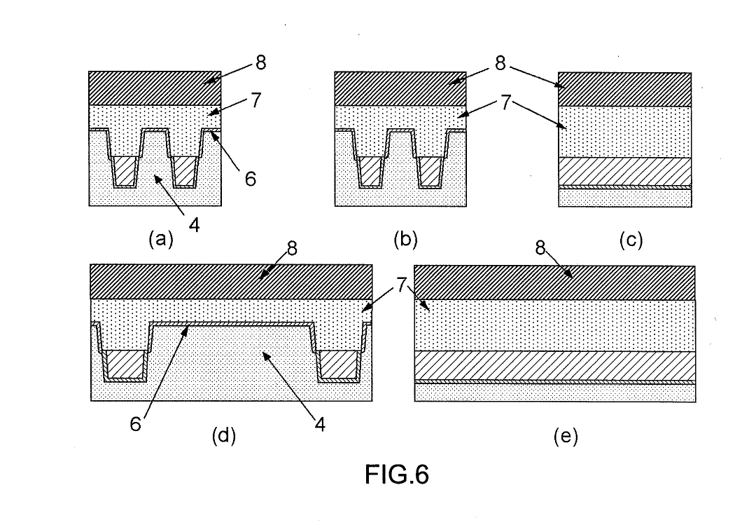

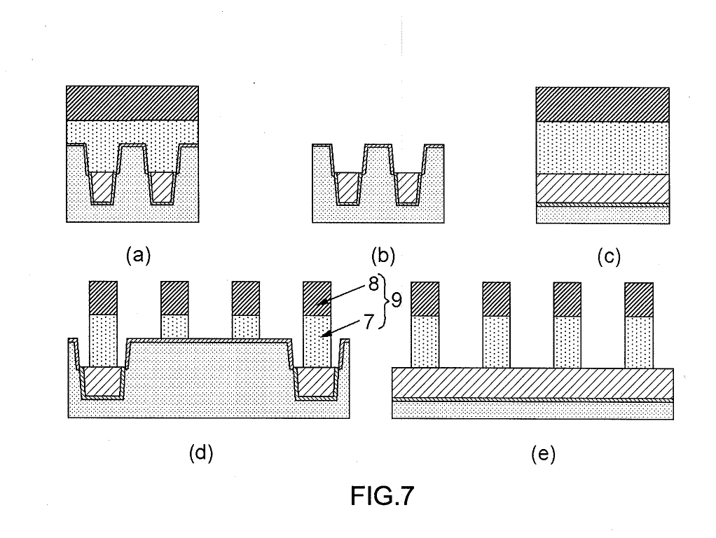

Next, thermal oxidation is performed to form gate insulating film 6 in about 6 to 7 nm thick. Thereafter, polysilicon 7 used as gate electrode 9 is formed in about 200 nm thick. Polysilicon 7 may contain a large amount of phosphorus or a large amount of boron. The impurity of polysilicon 7 may be introduced by implantation after a non-doped polysilicon film is once formed, or the impurity may be introduced at the time of film formation. (When the polysilicon containing a large amount of boron is used as the gate electrode, it is preferred to add nitrogen by nitriding gate insulating film 6.) After polysilicon 7 is formed, polysilicon 7 is planarized to about 70 nm from the upper surface of diffusion layer 4 by using the CMP technique. Thereafter, boron is implanted to form the channel region. The implantation condition is set to about 65 keV/5.0E¹² cm⁻³. Then, silicon nitride film 8 to be used as a hard mask is formed in about 70 nm (FIG. 6). At this time, polysilicon 7 is used as gate electrode 9. However, there may also be used a multilayer gate electrode structure such as a polycide structure having a silicide layer, such as WSi, on the polysilicon, or a poly metal structure having a metal, such as W, on the polysilicon. Thereafter, gate electrode 9 is patterned by using the lithography technique and the dry etching technique (FIG. 7).

Even when the width of STI and the thickness of polysilicon 7 are reduced due to the advancement of miniaturization, the STI oxide film region formed by etching based on the wet technique or the dry technique can be filled with oxide, and recessions and projections on the upper surface of the silicon are reduced. Thereby, even when the CMP for planarizing is not performed, it is possible to produce the polycide structure and poly metal structure.

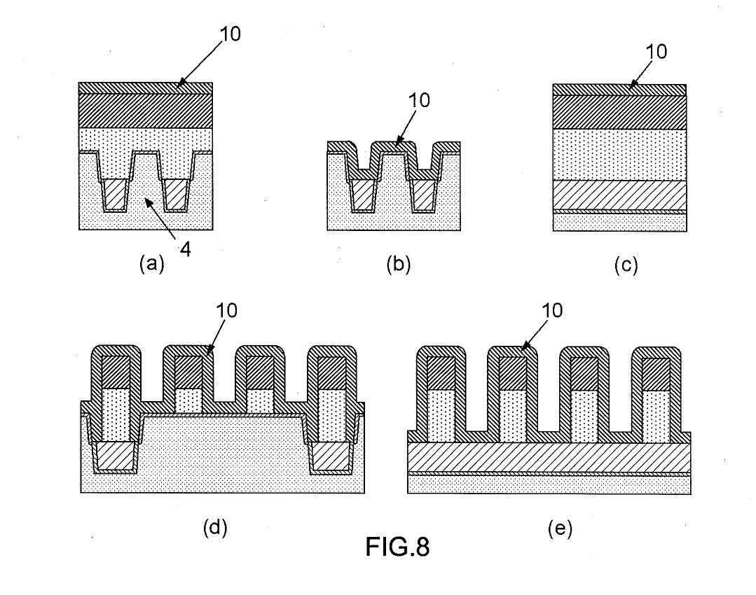

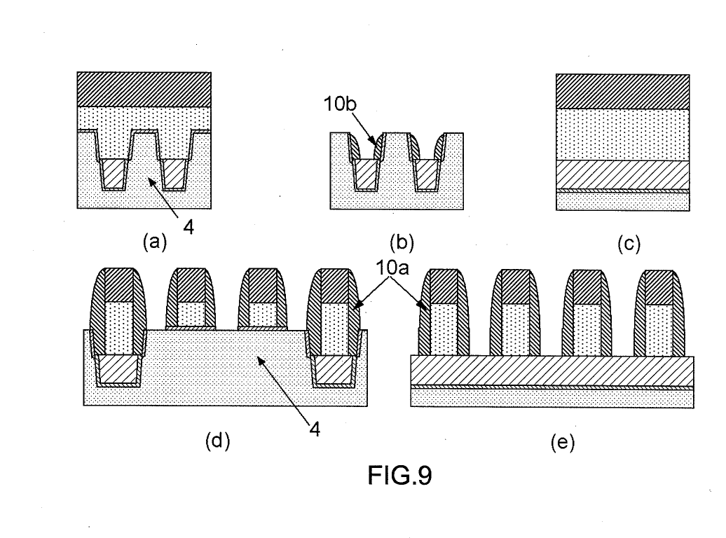

After patterning, the side surface portion of polysilicon of gate electrode 9 and the substrate are selectively oxidized to several nm by thermal oxidation. Then, after the implantation of LDD (Lightly Doped Drain) regions of peripheral transistors and cell transistors is performed, silicon nitride film 10 is formed in about 25 nm thick (FIG. 8), and then etched back by the dry etching technique. At this time, the nitride film only on the upper surface of diffusion layer 4 is removed, and SiN serving as SW 10a is left on the side surface of gate electrode 9. Further, since the STI oxide film is recessed to 100 nm also in the inside of the cell, SW 10b of silicon nitride film is also formed on the side surface of diffusion layer 4. At this time, the STI oxide film is also exposed (FIG. 9). In the exemplary embodiment, SW 10b of silicon nitride film is illustrated in a separated state. However, as the width of STI is reduced, the bottom portions of STI are connected to each other, or when the width of STI is further reduced, the STI is thoroughly filled with silicon nitride. These states may also be adopted.

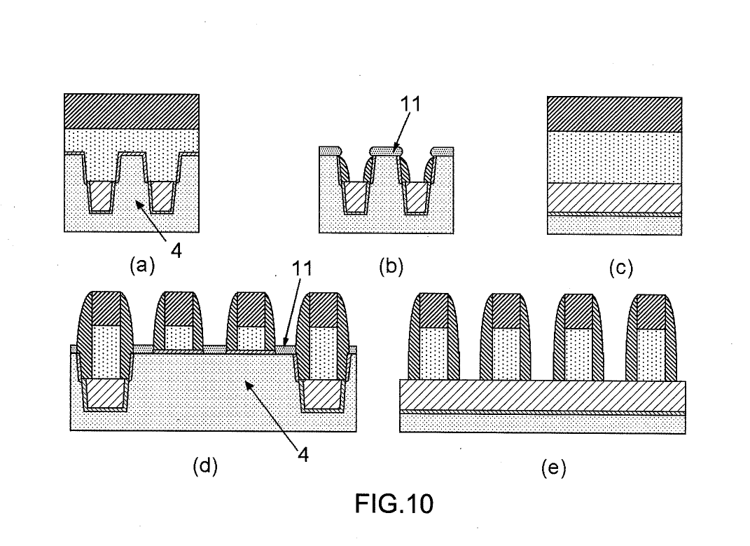

Thereafter, as a pretreatment to form selective epitaxial growth silicon, the wet treatment is performed by using a solution containing HF (for example, a dilute HF solution (HF:H₂O=1:500), so that a natural oxide film, which is formed on diffusion layer 4 exposed on the surface, is removed. Then, only on the region in which silicon is exposed, that is, only on the upper surface of diffusion layer 4, epitaxial growth silicon 11 is selectively grown to about 50 nm thick by the selective epitaxial technique. At this time, the side surface of diffusion layer 4 is covered by SW 10b of silicon nitride film, and hence epitaxial growth silicon 11 is not grown on the side surface of diffusion layer 4 (FIG. 10). Note that epitaxial growth silicon 11 is grown in the upward direction and, at the same time, is also grown in the lateral direction. Thus, the width of epitaxial growth silicon 11 is slightly increased in the width direction of diffusion layer 4, which direction is not regulated by SW 10a of gate electrode 9. Thereby, the parasitic resistance can be reduced. As for the formed thickness of epitaxial growth silicon 11, it is preferred that epitaxial growth silicon 11 is formed to have a lateral width greater than the width of diffusion layer 4. However, when epitaxial growth silicon 11 is formed excessively thick, there may be a case where epitaxial growth silicon 11 overrides SW 10b so as to be short circuited with adjacent epitaxial growth silicon 11. Therefore, it is usually preferred that, under the condition that the lateral growth of the epitaxial growth silicon is suppressed as much as possible, epitaxial growth silicon 11 is formed to grow to such an extent that epitaxial growth silicon 11 is not short circuited with epitaxial growth silicon of the adjacent diffusion layer. Further, as the thickness of epitaxial growth silicon 11, a thickness of about 50 to 70 nm is preferred in consideration of the condition of implantation after cell contact holes are opened as will be described below.

Further, in the case where the epitaxial growth silicon is used, when phosphorus and arsenic are implanted after the opening of cell contact holes as will be described below, the phosphorus and arsenic can be implanted at a high concentration into the surface of the epitaxial growth silicon, so that the parasitic resistance (contact resistance) can be reduced. Further, the distance between the bottom of cell contact plug and the end of the gate electrode is increased, so that a margin for the leakage of phosphorus from the cell contact plug is increased. For this reason, it is possible to increase the impurity concentration of the phosphorus doped amorphous silicon film which is buried as the cell contact plug, so that the parasitic resistance can be further reduced.

Further, since the epitaxial growth silicon layer is provided, the position, at which the electric field is increased due to the leakage of phosphorus from the cell contact plug, can be separated from the vicinity of the gate electrode, which also serves to improve the refreshing characteristics.

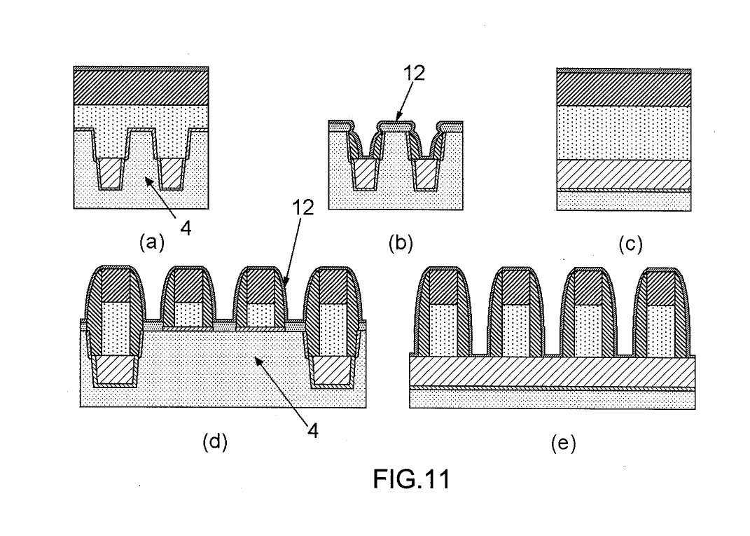

Next, silicon nitride film 12 is formed in a thickness of about 6 nm in order to improve a SAC (Self Align Contact) margin at the time when the cell contact holes are formed (FIG. 11). Further, although not shown, a TEOS-NSG film is formed in a thickness of about 55 nm on the semiconductor substrate and the transistors by the CVD method. Thereafter, only the peripheral transistor region is etched back by anisotropic etching using the lithography technique and the dry etching technique, so that the SW is formed. Thereafter, the TEOS-NSG film left in the cell is further removed by the wet treatment using the lithography technique in the state where the resist is opened only in the cell. The resist is removed by the dry etching technique after the wet treatment is finished.

Thereafter, a silicon nitride film (not shown) is formed in a thickness of several nm. Further, a BPSG film is formed in a thickness of about 600 nm to about 700 nm. Thereafter, the portion between the gate layers is filled with BPSG and the surface of the BPSG film is planarized by a reflow treatment at a temperature of about 800° C. and the CMP technique. Then, a TEOS-NSG film is formed in a thickness of about 50 nm on the BPSG film, so that there is formed first interlayer insulating film 13 made of the BPSG oxide film and the TEOS-NSG film.

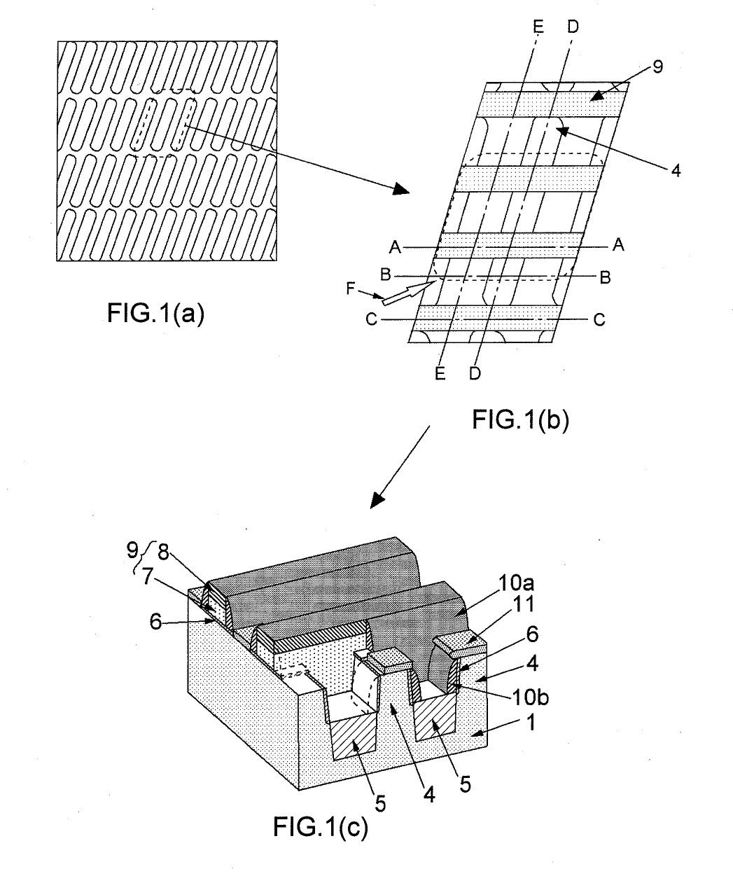

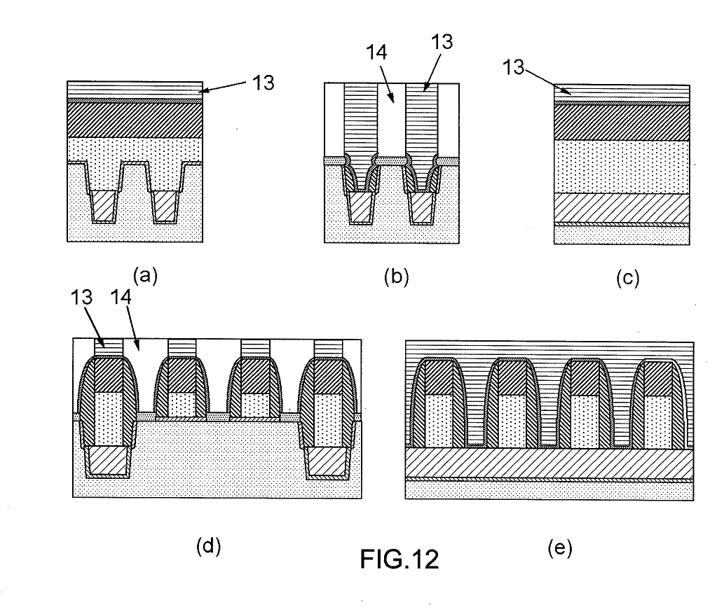

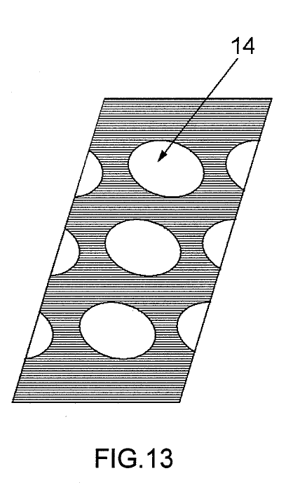

Finally, as shown in FIG. 12, there are formed cell contact holes 14 which are made to pass through first interlayer insulating film 13 and to reach selective epitaxial growth silicon 11. Cell contact hole 14 is etched to reach selective epitaxial growth silicon 11, and the surface of selective epitaxial growth silicon 11 is further over-etched by about 10 nm. FIG. 13 shows a top view corresponding to FIG. 1(b) at the time when cell contact holes 14 have been formed.

After forming cell contact holes 14, phosphorus and arsenic are implanted to a position shallower than the height of the Fin-FET (which is assumed to be 100 nm in the first exemplary embodiment), so that the source and drain regions are formed (the source electrode and the drain electrode (in the n-type diffusion layer in this case) are not shown). The implantation condition of phosphorus is set to about 30 keV/5.0E¹² cm⁻³. The implantation condition of arsenic is set to about 25 keV/1.0E¹³ cm⁻³.

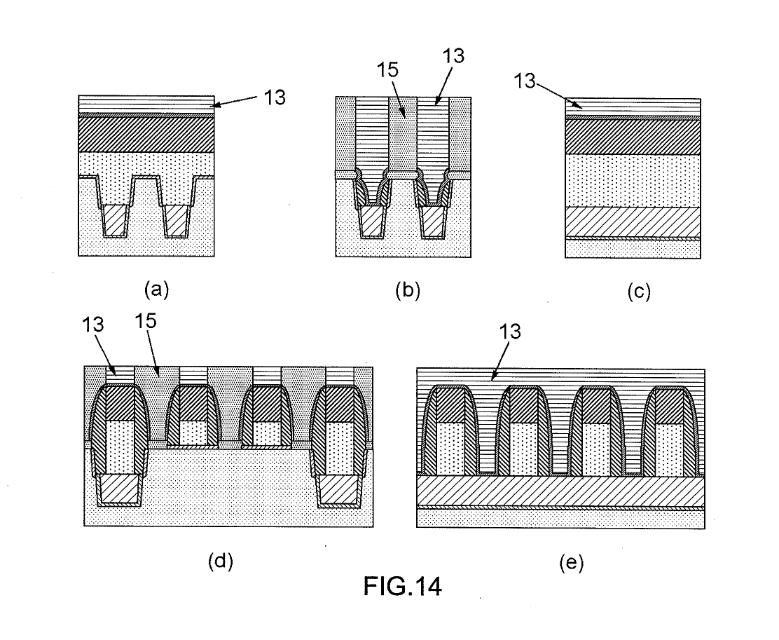

After the implantation, the amorphous silicon film, in which a large amount of phosphorus is doped, is filled in cell contact holes 14, and is deposited on first interlayer insulating film 13. Then, only the first silicon film on first interlayer insulating film 13 is removed by etch-back using the dry etching technique and by the CMP technique, so that cell contact plugs 15 are formed (FIG. 14). Note that the impurity concentration of the amorphous silicon film, in which phosphorus is doped, is set to 1.0×10²⁰ to 4.5×10²⁰ cm⁻³. After forming cell contact plugs 15, the formation of a plasma oxide film (not shown) having a thickness of about 200 nm, and heat treatment for activating the impurities of the contact plugs are performed.

In the first exemplary embodiment, the amorphous silicon film, in which a large amount of phosphorus is doped, is used for the cell contact plug. However, it is possible to further reduce the resistance of the cell contact plug by using a high melting point metal, such as W. However, when the high melting point metal is used, it is preferred to use a barrier metal, such as TiN, WN₂ and TaN, which prevents the diffusion of the high melting point metal.

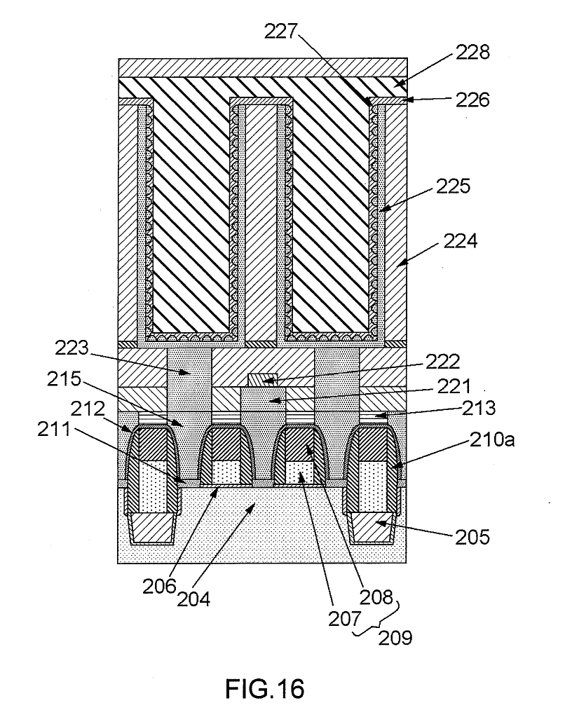

Thereafter, contacts of the peripheral transistors, and bit lines which are used to provide potentials to all of the transistors and portions, capacitors, wirings (Al and Cu) and the like are formed (not shown) by using a known method. Thereby, it is possible to produce a DRAM in which the Fin-FET is used as the cell array transistor. For example, FIG. 16 shows a cross-sectional structure after forming the capacitors. In the figure, on the cross-sectional structure shown in FIG. 14(d) (however, respective reference numerals are changed to those on the order of 200), bit contact plug 221 connected to bit line 222, and capacitor contact plugs 223 connected to capacitors are respectively formed on the SN (Storage-Node) side. Also, cylinder type capacitors, each of which is configured by lower electrode polysilicon 225, capacitive insulating film 226, and upper electrode metal 228, are formed in holes formed in capacitor core oxide film 224. Further, HSG (Hemi-Spherical Grain silicon) 227 is formed on the surface of lower electrode polysilicon 225, so that the capacitor area is secured.

In the exemplary embodiment shown in FIG. 16, an MIS (Metal Insulator Semiconductor) structure, in which polysilicon with the HSG formed thereon is used as the lower electrode, is used for the concave type capacitor structure. However, in order to cope with further miniaturization, there may also be used an MIM (Metal Insulator Metal) structure in which TiN, TaN, WN₂, and the like, are used for the upper electrode and the lower electrode, and in which a single layer of one of high dielectric constant films made of SiO₂, Si₃N₄, Ta₂O₅, Al₂O₃, HfO₂, ZrO₂, and the like, or a layer formed by laminating the high dielectric constant films is used as the capacitive insulating film. There may be used a crown type capacitor structure in which the outer side of the lower electrode is also used.

In the first exemplary embodiment, diffusion layer 4 is tapered. Thus, when the thickness of the insulating film formed for SW 10b is further reduced due to miniaturization, there is a possibility that the bottom side of the diffusion layer is exposed after the pretreatment (using the solution containing HF) before epitaxial growth silicon is selectively grown. In the following, there will be described a second exemplary embodiment in which a countermeasure against this problem is taken.

### Second Exemplary Embodiment

Similarly to the first exemplary embodiment, Si is etched to a depth of about 200 nm by the dry technique using a field nitride film as a mask. At this time, a portion of diffusion layer 104 above an STI oxide film, that is, the portion having a depth of 100 nm above the STI oxide film is vertically recessed (in the second exemplary embodiment, the STI oxide film is etched to a depth of about 100 nm in the subsequent process), and the portion under the vertically recessed portion is formed in a tapered shape. All of the portion having the depth of 200 nm may be formed in a vertical shape (not shown).

Further, after the gate electrode is formed similarly to FIG. 4 to FIG. 9 in the first exemplary embodiment, SiN serving as the SW is left on the side surface of the gate electrode. Further, since the STI oxide film is recessed to the depth of 100 nm in the cell, the vertically shaped portion of diffusion layer 104 is exposed on the surface of the portion, so that SW 110b of the silicon nitride film is also formed on the side surface. Since the recessed portion for SW 110b at this time is not formed in the taper shape as in the case of the first exemplary embodiment, the thickness of the insulating film on the bottom side of the diffusion layer is not reduced even due to the advancement of miniaturization. As a result, SW 110b can be surely formed.

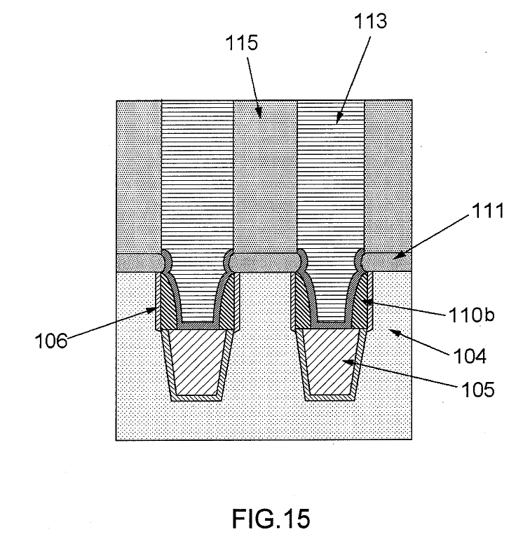

FIG. 15 shows a state where cell contact plugs 115 are formed by processes similar to the processes shown in FIG. 10 to FIG. 14 in the first exemplary embodiment after the above described processes. FIG. 15 corresponds to FIG. 14(b). Thereafter, contacts of the peripheral transistors, and bit lines, which are used to provide potentials to all of the transistors and portions, capacitors, wirings (Al and Cu), and the like are formed (not shown) by using a known method. Thereby, it is possible to produce a DRAM in which the Fin-FET is used for the cell array transistor.

By this method, the SW can be more surely formed on the side surface of the diffusion layer as compared with the case of the first exemplary embodiment, and the selective epitaxial growth silicon films on the surface of the diffusion layer side can be prevented from being brought into contact with each other. Thereby, the diffusion layers can be brought closer to each other, and hence the miniaturization can be further advanced. Further, the second exemplary embodiment is described by using the production flow of DRAM cell transistors, but transistors used in logic circuits can be produced by the same method.

Note that in the exemplary embodiments, there is used polysilicon which contains a large amount of phosphorus in the cell contact plug. However, as a measure to reduce the resistance in the case where the size of the cell contact hole is further reduced due to the further advancement of miniaturization, it is also possible to use a cell contact plug formed in such a manner that after phosphorus and arsenic are implanted subsequently to the opening of the cell contact holes, a refractory metal, such as W, is buried in the cell contact hole via a barrier metal, such as TiN and TaN. Also in this case, an excellent ohmic contact can be formed by implanting high concentration impurities into the epitaxial growth silicon surface.

It is apparent that the present invention is not limited to the above embodiments, but may be modified and changed without departing from the scope and spirit of the invention.

What is claimed is:

1. A semiconductor device which comprises a field effect transistor configured in a convex type Fin structure having a diffusion layer serving as source and drain regions formed in a semiconductor layer that is sandwiched by shallow trench isolation regions and projected upward of the isolation region; and having a gate electrode overlapping a channel region between the source and drain regions, the semiconductor device comprising: side walls on the sides of the diffusion layer serving as the source and drain regions; a selective epitaxial growth silicon layer on the upper surface of the diffusion layer sandwiched by the side walls; and a contact plug connected to the selective epitaxial growth silicon layer.

2. The semiconductor device according to claim 1, wherein the semiconductor layer has a width of 30 nm or less.

3. The semiconductor device according to claim 1, wherein the side surface of the diffusion layer configured in the convex type Fin structure is formed in a taper angle of 85° or more to less than 90°.

4. The semiconductor device according to claim 1, wherein the side surface of the diffusion layer configured in the convex Fin structure is formed in a vertical shape at least in a portion projected on the isolation region.

5. The semiconductor device according to claim 1, wherein after formation of the epitaxial growth silicon layer, the source and drain regions are formed by implanting an impurity via a contact hole opened to form the contact plug.

6. The semiconductor device according to claim 1, wherein the semiconductor device is a semiconductor memory device comprising, as a cell transistor, the field effect transistor configured in the convex type Fin structure.

7. The semiconductor device according to claim 2, wherein the semiconductor device is a semiconductor memory device comprising, as a cell transistor, the field effect transistor configured in the convex type Fin structure.

8. The semiconductor device according to claim 3, wherein the semiconductor device is a semiconductor memory device comprising, as a cell transistor, the field effect transistor configured in the convex type Fin structure.

9. The semiconductor device according to claim 4, wherein the semiconductor device is a semiconductor memory device comprising, as a cell transistor, the field effect transistor configured in the convex type Fin structure.

10. The semiconductor device according to claim 5, wherein the semiconductor device is a semiconductor memory device comprising, as a cell transistor, the field effect transistor configured in the convex type Fin structure.

11. A semiconductor device manufacturing method comprising:
forming a trench serving as a shallow trench isolation (STI) region on a semiconductor substrate;
forming the STI region by burying an insulating film in the trench;
etching back a part of the insulating film of the STI region to expose a semiconductor layer configured in a convex type Fin structure;
forming a gate insulating film on the exposed semiconductor layer;
forming, on the gate insulating film, a gate electrode overlapping a channel region between source and drain regions;
forming side walls on the sides of the gate electrode and on the sides of the semiconductor layer serving as the source and drain regions, and at the same time, exposing the upper surface of the semiconductor layer serving as the source and drain regions;
forming a selective epitaxial growth silicon layer on the exposed upper surface of the exposed semiconductor layer;
forming an interlayer insulating film and a contact hole connected to the semiconductor layer on which the selective epitaxial growth silicon layer is formed; and
forming a contact plug by burying a conductive material in the contact hole.

12. The semiconductor device manufacturing method according to claim 11, wherein the trench forming the STI region is formed in a taper angle of 85° or more to less than 90°.

13. The semiconductor device manufacturing method according to claim 11, wherein the trench forming the STI region is formed so that at least a portion of the semiconductor layer, which portion is projected on the isolation region, is formed in a vertical shape.

14. The semiconductor device manufacturing method according to claim 11, wherein after formation of the epitaxial growth silicon layer, the source and drain regions are formed as a diffusion layer by implanting an impurity via the contact hole opened to form the contact plug.

15. The semiconductor device manufacturing method according to claim 12, wherein after formation of the epitaxial growth silicon layer, the source and drain regions are formed as a diffusion layer by implanting an impurity via the contact hole opened to form the contact plug.

16. The semiconductor device manufacturing method according to claim 13, wherein after formation of the epitaxial growth silicon layer, the source and drain regions are formed as a diffusion layer by implanting an impurity via the contact hole opened to form the contact plug.
